(19) United States
(12) Patent Application Publication
(10) Pub. No.: US 2025/0098284 A1
(43) Pub. Date: Mar. 20, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Hiroki NEMOTO, Fuchu Tokyo (JP); Tsuyoshi KACHI, Kanazawa Ishikawa (JP); Hiroaki KATOU, Nonoichi Ishikawa (JP)

(21) Appl. No.: 18/592,204

(22) Filed: Feb. 29, 2024

(30) Foreign Application Priority Data
Sep. 19, 2023 (JP) 2023-151731

(51) Int. Cl. H01L 29/78; H01L 29/10; H01L 29/40; H01L 29/47; H01L 29/49; H01L 29/66

(52) U.S. Cl. CPC H10D 84/146; H10D 30/0295; H10D 30/0297; H10D 62/393; H10D 64/117; H10D 64/64; H10D 30/668; H10D 64/661; H10D 84/144

(57) ABSTRACT

A semiconductor device includes a semiconductor layer having first and second surfaces and including a first semiconductor region of a first type, first and second electrodes, a first insulation region, a first conductive portion electrically connected to the first electrode, a second insulation region, a first control electrode in the second insulation region, a second semiconductor region of the first type between the first and second insulation regions, a second conductive portion adjacent to the second semiconductor region and forming a Schottky junction with the second semiconductor region, a third semiconductor region of a second type on the first semiconductor region, and a fourth semiconductor region of the first type between the third semiconductor region and the first electrode. The third and fourth semiconductor regions are electrically connected to the first electrode.

### CROSS-REFERENCE TO RELATED APPLICATION(S)

This application is based upon and claims the benefit of priority from Japanese Patent Application No. 2023-151731, filed Sep. 19, 2023, the entire contents of which are incorporated herein by reference.

### FIELD

Embodiments described herein relate generally to a semiconductor device and a manufacturing method of a semiconductor device.

### BACKGROUND

A power metal oxide semiconductor field effect transistor (MOSFET) is used for an inverter for driving a motor or the like. In such a power MOSFET, when a body diode (or a parasitic diode) formed therein is switched from a forward operation to a reverse operation, a great recovery loss occurs due to minority carriers remaining in the diode.

The recovery loss can be suppressed by reducing the amount of minority carriers injected into the drift region of the diode during the forward operation, so that a reverse recovery charge is reduced. However, it is difficult to sufficiently reduce the reverse recovery charge with this method.

### BRIEF DESCRIPTION OF THE DRAWINGS

FIG. 1 is a cross-sectional view of a semiconductor device according to a first embodiment.

FIG. 2 is a cross-sectional view of the region A of the semiconductor device shown in FIG. 1.

FIG. 3 is a cross-sectional view of the periphery of a gate electrode in the semiconductor device according to the first embodiment.

FIG. 4 is a cross-sectional view of the semiconductor device according to the first embodiment for illustrating its operations.

FIG. 5A is a cross-sectional view for illustrating a manufacturing process of the semiconductor device according to the first embodiment.

FIG. 5B is a cross-sectional view for illustrating the manufacturing process of the semiconductor device according to the first embodiment.

FIG. 5C is a cross-sectional view for illustrating the manufacturing process of the semiconductor device according to the first embodiment.

FIG. 5D is a cross-sectional view for illustrating the manufacturing process of the semiconductor device according to the first embodiment.

FIG. 5E is a cross-sectional view for illustrating the manufacturing process of the semiconductor device according to the first embodiment.

FIG. 5F is a cross-sectional view for illustrating the manufacturing process of the semiconductor device according to the first embodiment.

FIG. 6 is a cross-sectional view of a semiconductor device according to a second embodiment.

FIG. 7 is a cross-sectional view of a semiconductor device according to a modification of the second embodiment.

FIG. 8 is a cross-sectional view of a semiconductor device according to another modification of the second embodiment.

FIG. 9 is a cross-sectional view of a semiconductor device according to a third embodiment.

### DETAILED DESCRIPTION

Embodiments provide a semiconductor device capable of reducing a reverse recovery charge.

In general, according to one embodiment, a semiconductor device comprises a semiconductor layer having first and second surfaces and including a first semiconductor region of a first type, a first electrode extending along the first surface, a second electrode extending along the second surface, a first insulation region extending from the first surface into the first semiconductor region, a first conductive portion in the first insulation region and electrically connected to the first electrode, a second insulation region extending from the first surface into the first semiconductor region and adjacent to the first insulation region, a first control electrode in the second insulation region, a second semiconductor region of the first type between and adjacent to the first and second insulation regions, a second conductive portion adjacent to the second semiconductor region along the first surface, the second conductive portion being connected to the first electrode and forming a Schottky junction with the second semiconductor region, a third semiconductor region of a second type on the first semiconductor region, the first control electrode being between the second and third semiconductor regions, and a fourth semiconductor region of the first type between the third semiconductor region and the first electrode. The third and fourth semiconductor regions are electrically connected to the first electrode.

Hereinafter, embodiments according to the present disclosure will be described with reference to the drawings. The embodiments do not limit the present disclosure. The drawings are schematic and conceptual, and a ratio of each part or the like shown in the drawings is not necessarily the same as that of an actual one. In the specification and drawings, the same reference signs are given to the component similar to that in the previously described drawings to eliminate the detailed description in an appropriate manner.

For convenience of description, in a stacking direction (thickness direction) of a semiconductor device, the side of a source electrode is also referred to as “upper” and the side of a drain electrode is also referred to as “lower”. However, these expressions are unrelated to the direction of gravity.

In the following description, notations of n+, n, and n− and p+, p, and p− may be used to represent the relative level of the impurity concentration in each conductivity type. That is, n+ represents that n-type impurity concentration is relatively higher than that of n, and n− represents that n-type impurity concentration is relatively lower than that of n. In addition, p+ represents that p-type impurity concentration is relatively higher than that of p, and p− represents that p-type impurity concentration is relatively lower than that of p. In one embodiment, n-type, n+-type, and n−-type are referred to as first conductivity types, and p-type, p+-type, and p−-type are referred to as second conductivity types. However, n-type and p-type may be inverted. That is, the first conductivity type may be p-type.

### First Embodiment

### <Semiconductor Device>

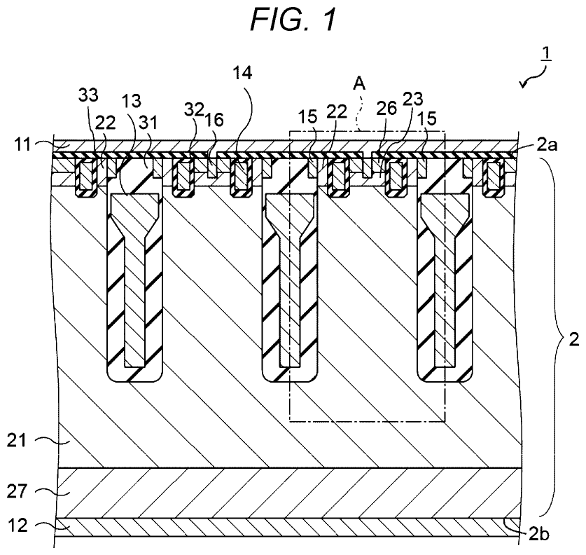

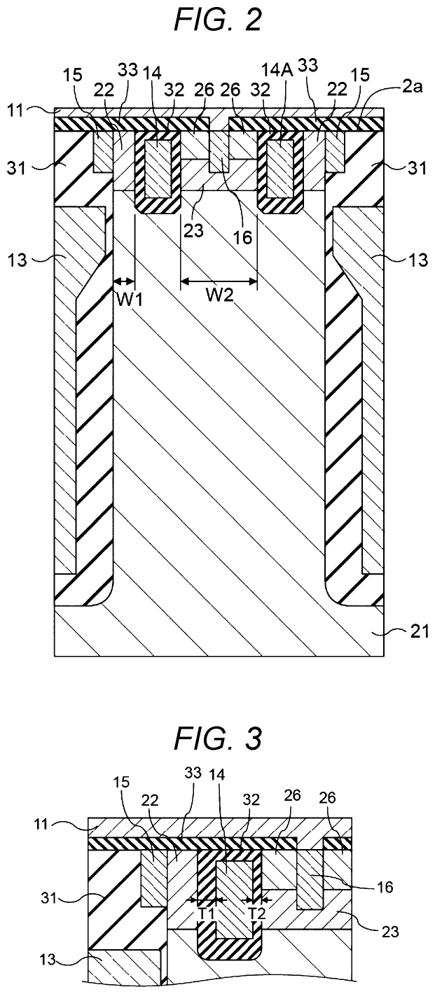

With reference to FIG. 1 to FIG. 3, a semiconductor device 1 according to a first embodiment will be described. FIG. 1 is a cross-sectional view of the semiconductor device 1 according to the first embodiment. FIG. 2 is a cross-sectional view of the region A shown in FIG. 1. FIG. 3 is a cross-sectional view of the periphery of a gate electrode 14 in the semiconductor device 1 according to the first embodiment.

By incorporating a Schottky barrier diode in a vertical MOSFET, the semiconductor device 1 according to the present embodiment reduces an amount of minority carriers injected into a drift region to reduce a reverse recovery charge Qrr at the time of a forward operation of a body diode, that is, when an electric current flows from a source electrode to a drain electrode. That is, the semiconductor device 1 includes the vertical MOSFET and the Schottky barrier diode. Though described later in details, the vertical MOSFET includes a source electrode 11, a drain electrode 12, a gate electrode 14, a drift region 21, a base region 23, a source region 26, and a drain region 27. The Schottky barrier diode includes a Schottky barrier metal 15 and an n-type region 22.

As illustrated in FIG. 1, the semiconductor device 1 includes a semiconductor layer 2, the source electrode 11 provided on an upper surface 2a of the semiconductor layer 2, and the drain electrode 12 provided on a lower surface 2b of the semiconductor layer 2. In the following examples, the upper surface 2a and the lower surface 2b of the semiconductor layer 2 are substantially planar, but this does not limit the shape of the semiconductor layer 2.

The semiconductor layer 2 is disposed on the drain electrode 12. The semiconductor layer 2 may be an epitaxial layer or a semiconductor substrate, or the semiconductor substrate and the epitaxial layer disposed thereon. In one embodiment, the semiconductor layer 2 is silicon (Si). In such a case, as an n-type impurity, for example, arsenic (As), phosphorus (P), or stibium (Sb) are used, and as a p-type impurity, for example, boron (B) is used. It should be noted that the semiconductor layer 2 may be a compound semiconductor such as silicon carbide (SiC) or gallium nitride (GaN).

The source electrode 11 is an electrode that functions as a source electrode of the MOSFET. The source electrode 11 is electrically connected to a field plate (FP) electrode 13 and a contact portion 16. In addition, the source electrode 11 is electrically connected to the Schottky barrier metal 15. The source electrode 11 is, for example, copper (Cu), titanium (Ti), tungsten (W), or aluminum (Al).

The drain electrode 12 is an electrode that functions as a drain electrode of the MOSFET. The drain electrode 12 forms an ohmic junction with the drain region 27. The drain electrode 12 is a metal such as copper, titanium, tungsten, or aluminum.

The FP electrode 13, the gate electrode 14, the Schottky barrier metal 15, the contact portion 16, the drift region 21, the n-type region 22, the base region 23, the source region 26, the drain region 27, an FP insulation film 31, and a gate insulation film 32 are provided in the semiconductor layer 2. An interlayer insulation film 33 is provided on the upper surface 2a of the semiconductor layer 2. Hereinafter, each component provided in the semiconductor layer 2 will be described.

The FP electrode 13 is disposed in the FP insulation film 31. That is, the FP electrode 13 is disposed to be adjacent to the drift region 21 via the FP insulation film 31. The FP electrode 13 is electrically connected to the source electrode 11. The FP electrode 13 is provided for relaxing concentration of a reverse direction electric field (i.e., FP effect) between the gate electrode 14 and the drain electrode 12 to improve pressure-resistance of the semiconductor device 1. In the present embodiment, in order to further improve the pressure-resistance, the upper part of the FP electrode 13 is wider than the lower part of the FP electrode 13 so that the distance between the FP electrode 13 and the base region 23 is shortened. The shape of the FP electrode 13 is not limited to the shapes illustrated in FIG. 1 and FIG. 2, and is optional. The FP electrode 13 is polysilicon, for example. The FP electrode 13 may contain p-type or n-type impurity.

In the present embodiment, as illustrated in FIG. 2, the upper end of the FP electrode 13 is located at the lower position than the position of the lower end of the n-type region 22.

The gate electrode 14 is an electrode that functions as a gate electrode of the MOSFET. The gate electrode 14 is disposed in the gate insulation film 32. The upper end of the gate electrode 14 is located, for example, at a higher position than the position of the upper end of the base region 23, and the lower end of the gate electrode 14 is located, for example, at a lower position than the lower end of the base region 23. The gate electrode 14 is disposed to be adjacent to the base region 23 via the gate insulation film 32. The gate electrode 14 is polysilicon, for example.

The gate electrode 14 may contain p-type or n-type impurity. In a case where the gate electrode 14 contains p-type impurity, it is possible to stabilize an operation of the MOSFET provided in the semiconductor device 1. In a case where the gate electrode 14 contains n-type impurity, it is possible to stabilize an operation of the Schottky barrier diode provided in the semiconductor device 1.

The Schottky barrier metal 15 is an electrode that functions as an anode electrode of the Schottky barrier diode. The Schottky barrier metal 15 comprises a metal such as platinum (Pt), cobalt (Co), or nickel (Ni) and forms the Schottky junction from/to the n-type region 22. The Schottky barrier metal 15 is electrically connected to the source electrode 11. In the present embodiment, the Schottky barrier metal 15 and the source electrode 11 are electrically connected in a depth direction of the paper sheets of FIG. 1 and FIG. 2. It should be noted that the Schottky barrier metal 15 may be directly connected to the source electrode 11 in an element region that supplies an electric current illustrated in FIG. 2.

The Schottky barrier metal 15 is located on the opposite side of the gate electrode 14 across the n-type region 22. In the present embodiment, the Schottky barrier metal 15 is provided in the PF insulation film 31 and is in contact with the n-type region 22. As illustrated in FIG. 2, the upper end of the Schottky barrier metal 15 reaches the upper surface 2a of the semiconductor layer 2, and the lower end of the Schottky barrier metal 15 is located at a height between the upper end and the lower end of the n-type region 22. The Schottky barrier metal 15 may extend to the lower end of the n-type region 22 or therebelow.

The Schottky barrier metal 15 may be provided in the n-type region 22 to be in contact with the FP insulation film 31 or cross over a boundary between the FP insulation film 31 and the n-type region 22.

In addition, in a case where the Schottky barrier metal 15 comprises platinum, the Schottky barrier metal 15 can be formed by sputtering and then, heat processing may be performed to diffuse platinum atoms in the drift region 21. Since the platinum acts as a lifetime killer that captures carriers promptly, the reverse recovery charge Qrr of the semiconductor device 1 can be further reduced.

The contact portion 16 is electrically connected to the source electrode 11 and functions as a source electrode of the MOSFET together with the source electrode 11. As illustrated in FIG. 2, the contact portion 16 is provided in the base region 23 and the source region 26, and forms an ohmic junction with the base region 23 and the source region 26. The contact portion 16 is, for example, copper, titanium, tungsten, or aluminum. In order to reduce resistance against the contact portion 16, a semiconductor region having a higher impurity concentration of the second conductivity type than that of the base region 23 may be provided to wrap the top end of the contact portion 16.

The drift region 21 is a semiconductor region that functions as a drift region of the MOSFET. The drift region 21 is disposed on the drain region 27 above the drain electrode 12. The drift region 21 is an n-type semiconductor region, for example. The n-type impurity concentration of the drift region 21 is, for example, 1×1015 cm-3 or more and 2×1016 cm-3 or less.

The n-type region 22 is a semiconductor region in which the Schottky barrier diode is formed. As illustrated in FIG. 2, in the vertical direction, the n-type region 22 is disposed on the drift region 21. In the horizontal direction, the n-type region 22 is located between the FP insulation film 31 and the gate insulation film 32 and is in contact with the FP insulation film 31 and the gate insulation film 32. The n-type impurity concentration of the n-type region 22 is, for example, equal to or less than the n-type impurity concentration of the drift region 21 and is 1×1013 cm-3 or more and 11015 cm-3 or less. It should be noted that if within the range where the Schottky junction is formed between the Schottky barrier metal 15 and the n-type region 22, the n-type impurity concentration of the n-type region 22 may be higher than the n-type impurity concentration of the drift region 21.

The base region 23 is a semiconductor region that functions as a base region of the MOSFET. In the vertical direction, the base region 23 is disposed on the drift region 21. In the horizontal direction, the base region 23 is located on the opposite side of the n-type region 22 across the gate electrode 14 and the gate insulation film 32. In a case where a voltage is applied to the gate electrode 14, a channel is formed in the base region 23 and carriers pass through between the drift region 21 and the source region 26. The base region 23 is a p-type semiconductor region, for example. The p-type impurity concentration of the base region 23 is, for example, 1×1016 cm-3 or more and 1×1020 cm-3 or less.

As illustrated in FIG. 2, in the present embodiment, a width W1 of the n-type region 22 is narrower than a width W2 of the base region 23. In more details, the semiconductor device 1 is provided in the semiconductor layer 2 and further includes a second gate electrode 14A located on the opposite side of the gate electrode 14 across the contact portion 16. The width W1 of the n-type region 22 is narrower than the width W2 of the base region 23 between the gate electrode 14 and the second gate electrode 14A. With this configuration, the pressure-resistance of the semiconductor device 1 can be improved. It should be noted that the gate electrode 14 and the second gate electrode 14A are functionally identical, so that, in the following description, both are referred to as the gate electrode 14.

The source region 26 is a semiconductor region that functions as a source region of the MOSFET. In the vertical direction, the source region 26 is disposed between the base region 23 and the source electrode 11. In horizontal direction, the source region 26 is located between the gate insulation film 32 and the contact portion 16 and is in contact with the contact portion 16. The source region 26 is an n+-type semiconductor region, for example. The n-type impurity concentration of the source region 26 is, for example, 1×1018 cm-3 or more and 1×1022 cm-3 or less.

The drain region 27 is a semiconductor region that functions as a drain region of the MOSFET. As illustrated in FIG. 1, the drain region 27 is disposed on the drain electrode 12. The drain region 27 is disposed between the drain electrode 12 and the drift region 21. The drain region 27 is an n+-type semiconductor region, for example. The n-type impurity concentration of the drain region 27 is, for example, 1×1018 cm-3 or more and 1×1021 cm-3 or less.

Both or at least one of the drift region 21 and the drain region 27 can form a semiconductor region.

The FP insulation film 31 is an insulation film for electrically insulating the FP electrode 13 from the semiconductor layer 2. The FP insulation film 31 is provided to reach the drift region 21 from the upper surface 2a of the semiconductor layer 2. The FP insulation film 31 is an insulation material filled in a field plate trench provided to reach the drift region 21 from the upper surface 2a. As illustrated in FIG. 1 and FIG. 2, the FP insulation film 31 provided to fill the field plate trench is in contact with the drift region 21 and the n-type region 22. In the present embodiment, the field plate trench is provided on the upper surface 2a of the semiconductor layer 2, but this does not limit the shape of the semiconductor layer 2. The FP insulation film 31 is an insulation material which is, for example, silicon oxide or silicon nitride.

The gate insulation film 32 is an insulation film for electrically insulating the gate electrode 14 from the semiconductor layer 2. The gate insulation film 32 is provided to reach the drift region 21 from the upper surface 2a of the semiconductor layer 2 and be adjacent to the FP insulation film 31. The gate insulation film 32 is an insulation material filled in a gate trench. The gate trench is a trench different from the above-described field plate trench and provided to be shallower than the field plate trench. In the present embodiment, the gate trench is provided on the upper surface 2a of the semiconductor layer 2, but this does not limit the shape of the semiconductor layer 2.

The drift region 21, the n-type region 22, the base region 23, and the source region 26 are disposed around the gate insulation film 32. The gate insulation film 32 is an insulation material which is, for example, silicon oxide or silicon nitride.

As illustrated in FIG. 3, a thickness T1 of the gate insulation film 32 at the side of the n-type region 22 is thicker than a thickness T2 of the gate insulation film 32 at the side of the base region 23. With this configuration, the thickness T1 at the side of the n-type region 22 can be increased without any change of the width of the gate electrode 14 or the width of the gate trench, enabling improvement of the pressure-resistance of the Schottky barrier diode provided in the semiconductor device 1. In details, even in a case where the gate electrode 14 contains n-type impurities, by making the thickness T1 thicker than the thickness T2, sufficient pressure-resistance can be secured due to the depletion layer extending from the Schottky barrier metal 15. In a case where the gate electrode 14 contains p-type impurities, by making the thickness T2 thicker than the thickness T1, pressure-resistance can be improved due to the depletion layer extending from the gate electrode 14. A relationship between the thicknesses T1 and T2 of the gate insulation film 32 is not limited the one described above. For example, the thickness T1 may be adjusted taking the pressure-resistance or insulation tolerance of the semiconductor device 1 into consideration and the thickness T2 may be adjusted taking the gate threshold voltage Vth or insulation tolerance of the semiconductor device 1.

The interlayer insulation film 33 is an insulation film for electrically insulating the source electrode 11 from the n-type region 22. In the example illustrated in FIG. 2, the interlayer insulation film 33 coats the upper surface 2a of the semiconductor layer 2 except the upper surface of the contact portion 16. By providing the interlayer insulation film 33, formation of the ohmic junction between the source electrode 11 and the n-type region 22 is suppressed, preventing degradation of a Schottky junction effect. It should be noted that the Schottky barrier metal 15 and the source electrode 11 may be in contact with each other while the interlayer insulation film 33 does not coat the Schottky barrier metal 15.

### <Operations of Semiconductor Device>

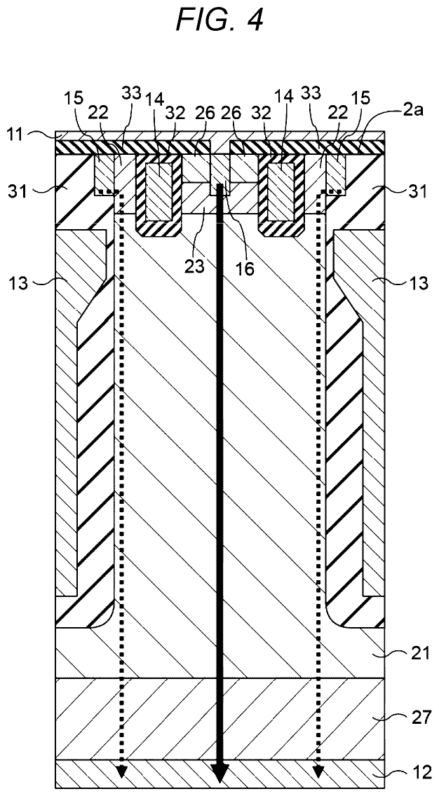

Next, with reference to FIG. 4, operations of the semiconductor device 1 will be described. FIG. 4 is a cross-sectional view of the semiconductor device 1 according to the first embodiment for illustrating its operations.

FIG. 4 illustrates the flow of electric currents in the semiconductor device 1 when the electric currents flow into the drain electrode 12 from the source electrode 11 of the semiconductor device 1. These electric currents flow to the drain electrode 12 when positive potential is applied to the source electrode 11, for example, in switching operations of the semiconductor device 1.

As illustrated in FIG. 4, the semiconductor device 1 according to the present embodiment includes a PIN diode including the base region 23, the drift region 21, and the drain region 27 as a body diode, and further includes the Schottky barrier diode including the Schottky barrier metal 15 and the n-type region 22. Therefore, as illustrated in FIG. 4, the electric currents that flow into the drain electrode 12 from the source electrode 11 include an electric current through a body diode (the solid line in FIG. 4) and electric currents through a Schottky barrier diode (the dot dash lines in FIG. 4).

In details, when the electric currents that flow into the drain electrode 12 from the source electrode 11 are small, or when a state in which the electric currents flow into the drain electrode 12 from the source electrode 11 is finished in a short time, mainly, the electric currents through the Schottky barrier diode illustrated by dotted lines in FIG. 4 flow in the semiconductor device 1. The reason is that a forward rising voltage of the Schottky barrier diode is small in comparison with a forward rising voltage of the body diode. Minority carriers are not accumulated in the Schottky barrier diode, so that the amount of the minority carriers injected into the drift region 21 can be reduced in comparison with the semiconductor device with no Schottky barrier diode. As a result, the reverse recovery charge Qrr of the semiconductor device 1 can be reduced.

On the other hand, when the electric currents that flow into the drain electrode 12 from the source electrode 11 are large, in addition to the electric currents through the Schottky barrier diode illustrated by dotted lines in FIG. 4, the electric currents through the body diode illustrated by solid lines in FIG. 4 flow. However, even in this case, by flowing a part of the electric currents flowing in the semiconductor device 1 as electric currents through the Schottky barrier diode, the electric currents through the body diode can be reduced. Therefore, in comparison with the semiconductor device having no Schottky barrier diode, the amount of minority carriers injected into the drift region 21 can be reduced and the reverse recovery charge Qrr of the semiconductor device 1 can be reduced.

As described above, according to the semiconductor device 1, the amount of minority carriers injected into the drift region 21 when electric currents flow to the drain electrode 12 from the source electrode 11, can be reduced and the reverse recovery charge Qrr can be reduced.

### <Manufacturing Method of Semiconductor Device>

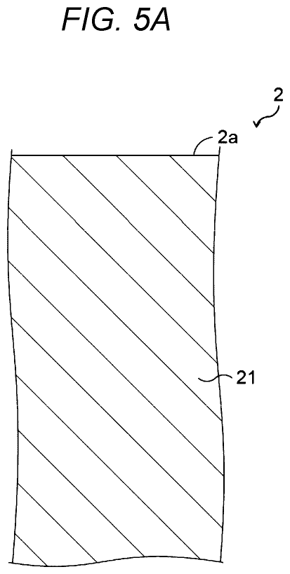

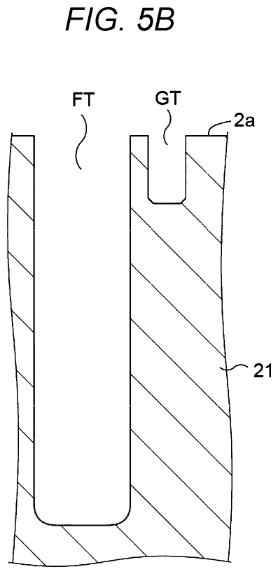

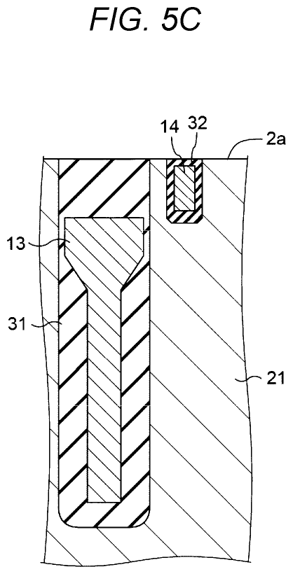

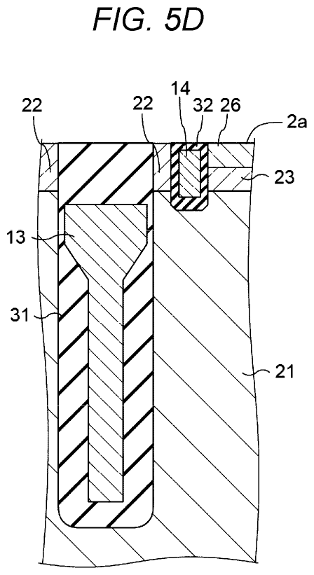

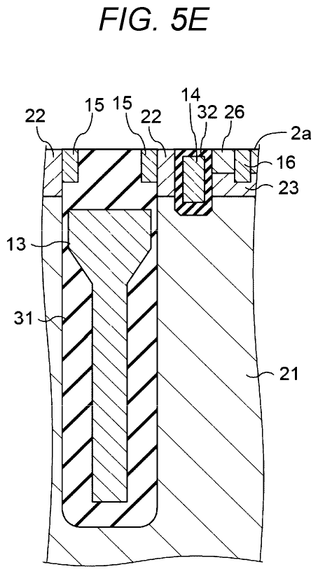

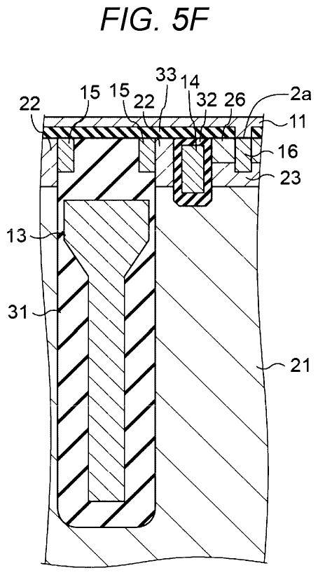

Next, with reference to FIG. 5A to FIG. 5F, an example of a manufacturing method of the semiconductor device 1 according to the present embodiment will be described. FIG. 5A to FIG. 5F are cross-sectional views for illustrating the manufacturing method of the semiconductor device 1.

First, as illustrated in FIG. 5A, the semiconductor layer 2 provided with the drift region 21 is prepared. The semiconductor layer 2 has the upper surface 2a.

Next, as illustrated in FIG. 5B, a field plate trench FT and a gate trench GT are formed through the upper surface 2a by reactive ion etching (RIE) or the like. The field plate trench FT is formed to be deeper than the gate trench GT. For example, the field plate trench FT and the gate trench GT are formed separately. Alternatively, the field plate trench FT and the gate trench GT may be formed at once.

As illustrated in FIG. 5C, an insulation material is deposited in the field plate trench FT and the gate trench GT by chemical vapor deposition (CVD) or the like to form the FP insulation film 31 and the gate insulation film 32. The insulation material is silicon oxide or silicon nitride, for example. Subsequently, some of the FP insulation film 31 and the gate insulation film 32 are removed by the RIE or the like. At this time, some of the FP insulation film 31 and the gate insulation film 32 are removed so that the upper part of the FP insulation film 31 widens. Next, the FP electrode 13 and the gate electrode 14 are formed on the portion from which the FP insulation film 31 and the gate insulation film 32 were removed. The FP electrode 13 and the gate electrode 14 are formed, for example, by depositing a conductive material such as polysilicon by CVD or the like and then, etching back the excess conductive material. The insulation material is deposited by CVD or the like to bury the FP electrode 13 and the gate electrode 14.

As illustrated in FIG. 5D, the n-type region 22 is formed by implanting impurity ions of the second conductivity type in the surface, which is a part of the upper surface 2a, between the FP insulation film 31 and the gate insulation film 32. It should be noted that in a case where the impurity concentration of the n-type region 22 is the same as that of the drift region 21, the present process is omitted.

Subsequently, the base region 23 is formed by implanting impurity ions of the second conductivity type in the surface, which is a part of the upper surface 2a, on which the n-type region 22, the FP insulation film 31, and the gate insulation film 32 are not provided. The source region 26 is formed by implanting impurity ions of the first conductivity type in the base region 23. It should be noted that the n-type region 22 and the base region 23 may be formed in any order. In addition, when the source region 26 is formed, an n+-type semiconductor region located on the n-type region 22 may be formed by implanting impurity ions of the first conductivity type also in the n-type region 22. The n-type impurity concentration is, for example, 1×1018 cm-3 or more and 1×1022 cm-3 or less.

As illustrated in FIG. 5E, some of the FP insulation film 31, the base region 23, and the source region 26 are removed by the RIE or the like. Then, a first metal material is deposited to fill the removed part of the FP insulation film 31 by physical vapor deposition (PVD) or the like to form the Schottky barrier metal 15. The first metal material comprises, for example, platinum, cobalt, and nickel. In addition, a second metal material is deposited to fill the removed parts of the base region 23 and the source region 26 by the PVD or the like to form the contact portion 16. The second metal material is, for example, copper, titanium, tungsten, and aluminum.

The Schottky barrier metal 15 and the contact portion 16 may be formed in any order.

In a case where the Schottky barrier metal 15 comprises platinum, heat processing may be performed after formation of the Schottky barrier metal 15. By performing the heat processing, platinum atoms can be diffused and act as a lifetime killer that captures carriers promptly.

As illustrated in FIG. 5F, the interlayer insulation film 33 is provided to coat at least the upper surface of the n-type region 22 of the upper surface 2a of the semiconductor layer 2. In the present embodiment, the interlayer insulation film 33 coats and covers the upper surface 2a except the upper surface of the contact portion 16. The interlayer insulation film 33 is an insulation material which is, for example, silicon oxide or silicon nitride.

As illustrated in FIG. 5F, the source electrode 11 is formed to bury the interlayer insulation film 33 in the upper surface 2a of the semiconductor layer 2.

Though not specifically illustrated, the drain region 27 may be formed by implanting impurity ions of the first conductivity type in the lower surface 2b of the semiconductor layer 2. Then, the drain electrode 12 is formed to coat the lower surface 2b of the semiconductor layer 2. The drain region 27 and the drain electrode 12 may be formed before the field plate trench FT and the gate trench GT are formed.

Through the above processes, the semiconductor device 1 is manufactured.

As described above, the semiconductor device 1 according to the first embodiment includes the n-type region 22 and the Schottky barrier metal 15. The n-type region 22 is provided in the semiconductor layer 2 and located between the FP insulation film 31 and the gate insulation film 32. The Schottky barrier metal 15 is located on the opposite side of the gate electrode 14 across the n-type region 22, forms the Schottky junction from/to the n-type region 22, and is electrically connected to the source electrode 11. With this configuration, when the electric currents flow to the drain electrode 12 from the source electrode 11 of the semiconductor device 1, electric currents flow in the Schottky barrier diode including the Schottky barrier metal 15 and the n-type region 22. As a result, the amount of minority carriers injected into the drift region 21 when the electric currents flow to the drain electrode 12 from the source electrode 11, can be reduced and the reverse recovery charge Qrr can be reduced.

### Second Embodiment

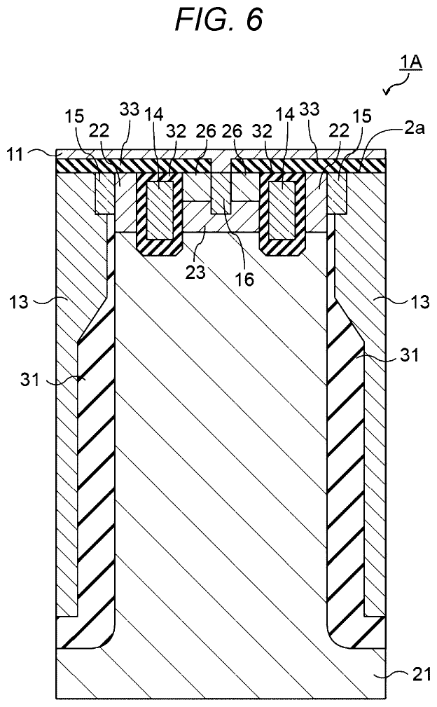

With reference to FIG. 6, a semiconductor device 1A according to a second embodiment will be described. FIG. 6 is a cross-sectional view of the semiconductor device 1A according to the second embodiment. One of the different points between the semiconductor device 1A according to the present embodiment and the above-described semiconductor device 1 according to the first embodiment is the location of the upper end of the FP electrode 13. Hereinafter, the semiconductor device 1A according to the present embodiment will be described from the viewpoint of the different points from the first embodiment.

As illustrated in FIG. 6, the upper end of the FP electrode 13 in the semiconductor device 1A according to the present embodiment is located at a substantially same height as the height of the upper surface 2a of the semiconductor layer 2. The FP electrode 13 is in contact with the Schottky barrier metal 15. That is, the FP electrode 13 is directly in contact with the Schottky barrier metal 15 without interposition of the FP insulation film 31.

As described above, in the second embodiment, the upper end of the FP electrode 13 is located at a substantially same height as the height of the upper surface 2a of the semiconductor layer 2. With this configuration, in a backward operation of the body diode, the depletion layer easily spreads around the n-type region 22 in comparison with the semiconductor device 1 according to the first embodiment, so that the pressure-resistance of the Schottky barrier diode provided in the semiconductor device 1A can be improved.

In addition, even in a case where the FP electrode 13 and the base region 23 are located more distantly, a sufficient FP effect is expected, so that the width of the n-type region 22 (e.g., width W1 in FIG. 2) can be widened. As a result, the ratio of the Schottky barrier diode to the body diode in the semiconductor device 1A can be further increased. Thus, the ratio of the electric currents that flow to the side of Schottky barrier diode when the electric currents flow to the drain electrode 12 from the source electrode 11, can be further increased and the reverse recovery charge Qrr of the semiconductor device 1A can be further reduced.

When the semiconductor device 1A is manufactured, a process of burying the FP insulation film 31 after formation of the FP electrode 13 is unnecessary, so that the manufacturing processes of the semiconductor device 1A can be simplified.

The upper end of the gate electrode 14 may also be located at a substantially same height as the height of the upper surface 2a. In this case, a process of forming an insulation film on the gate electrode 14 can be omitted and the manufacturing processes of the semiconductor device 1A can be further simplified.

### Modification 1 of Second Embodiment

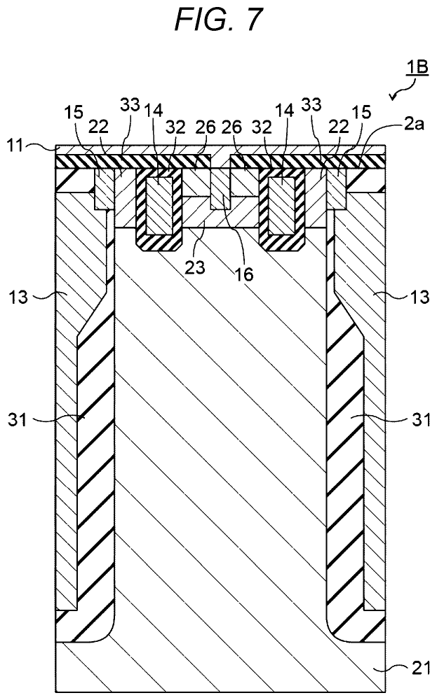

With reference to FIG. 7, a semiconductor device 1B according to a modification 1 of the second embodiment will be described. FIG. 7 is a cross-sectional view of the semiconductor device 1B according to the modification 1 of the second embodiment.

As illustrated in FIG. 7, the upper end of the FP electrode 13 in the semiconductor device 1B according to the modification 1 is located at a higher position than the position of the lower end of the Schottky barrier metal 15, but is located at a lower position than the position of the upper surface 2a of the semiconductor layer 2. With this configuration, similarly to the above-described second embodiment, the depletion layer easily spreads in comparison with the semiconductor device 1 according to the first embodiment, so that the pressure-resistance of the Schottky barrier diode provided in the semiconductor device 1B can be improved.

Even in a case where the FP electrode 13 and the base region 23 are located more distantly, an FP effect is expected, so that the width of the n-type region 22 (e.g., width W1 in FIG. 2) can be widened. As a result, the ratio of the Schottky barrier diode to the body diode in the semiconductor device 1B can be further increased. Thus, the ratio of the electric currents that flow to the side of Schottky barrier diode when the electric currents flow to the drain electrode 12 from the source electrode 11, can be further increased and the reverse recovery charge Qrr of the semiconductor device 1B can be further reduced.

In the semiconductor device 1B according to the present embodiment, the FP electrode 13 is in contact with the Schottky barrier metal 15. Thus, for example, separate wiring for connection between the FP electrode 13 and the source electrode 11 can be omitted.

### Modification 2 of Second Embodiment

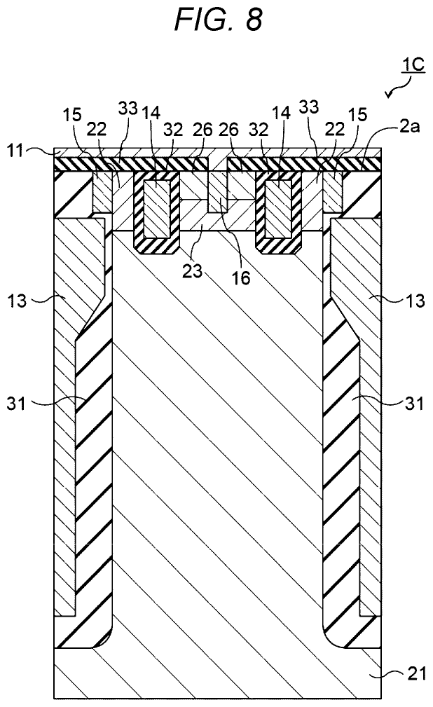

With reference to FIG. 8, a semiconductor device 1C according to a modification 2 of the second embodiment will be described. FIG. 8 is a cross-sectional view of the semiconductor device 1C according to the modification 2 of the second embodiment.

As illustrated in FIG. 8, the upper end of the FP electrode 13 in the semiconductor device 1C according to the present modification is located at a higher position than the position of the lower end of the n-type region 22. In addition, the FP electrode 13 is not in contact with the Schottky barrier metal 15.

Since the upper end of the FP electrode 13 is located at a higher position than the position of the lower end of the n-type region 22, similarly to the above-described second embodiment, the depletion layer easily spreads in comparison with the semiconductor device 1 according to the first embodiment, so that the pressure-resistance of the Schottky barrier diode provided in the semiconductor device 1C can be improved.

In addition, even in a case where the FP electrode 13 and the base region 23 are located more distantly, an FP effect is expected, so that the width of the n-type region 22 (e.g., width W1 in FIG. 2) can be widened. As a result, the ratio of the Schottky barrier diode to the body diode in the semiconductor device 1C can be further increased. Thus, the ratio of the electric currents that flow to the side of Schottky barrier diode when the electric currents flow to the drain electrode 12 from the source electrode 11, can be further increased and the reverse recovery charge Qrr of the semiconductor device 1C can be further reduced.

### Third Embodiment

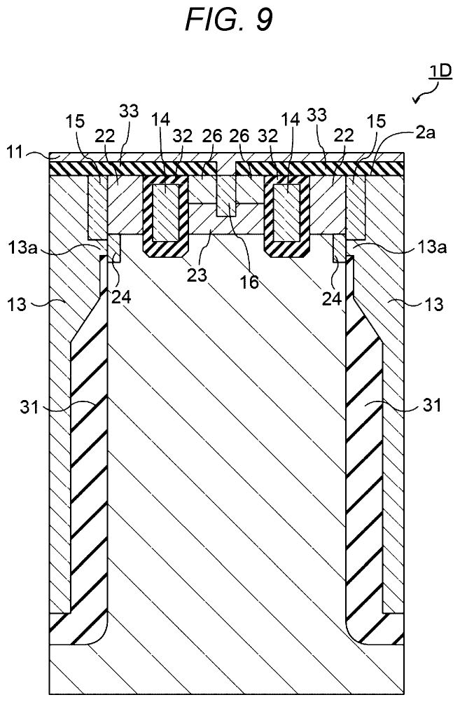

With reference to FIG. 9, a semiconductor device 1D according to a third embodiment will be described. FIG. 9 is a cross-sectional view of the semiconductor device 1D according to the third embodiment. Hereinafter, the semiconductor device 1D according to the present embodiment will be described from the viewpoint of the different points from the second embodiment.

As illustrated in FIG. 9, the FP electrode 13 in the semiconductor device 1D according to the present embodiment has, in a broad portion of the upper part thereof, a projection portion 13a projecting to the side surface of the FP insulation film 31, that is, the inner wall of the field plate trench.

The lower end of the Schottky barrier metal 15 is located at a lower position than the position of the lower end of the n-type region 22. This is for preventing contact between the projection portion 13a and the n-type region 22 and preventing degradation of the Schottky junction effect. Alternatively, the lower end of the Schottky barrier metal 15 may be located at a higher position than the position of the lower end of the n-type region 22 and an insulation film may be provided between the lower end of the Schottky barrier metal 15 and the upper end of the projection portion 13a to prevent contact between the projection portion 13a and n-type region 22.

The semiconductor device 1D further includes, in the semiconductor layer 2, a p-type region 24 which is a p-type semiconductor region provided between the projection portion 13a and the drift region 21. The p-type region 24 is provided to coat the projection portion 13a exposed from the FP insulation film 31 and is in contact with the projection portion 13a and the n-type region 22. In the present embodiment, the p-type region 24 is in contact with the projection portion 13a on the side surface thereof and is in contact with the n-type region 22 on the upper surface thereof. It should be noted that the upper surface of the p-type region 24 may not be in contact with the n-type region 22. The p-type region 24 has a narrower width than the width of the n-type region 22 and the drift region 21 exists between the p-type region 24 and the gate insulation film 32.

As illustrated in FIG. 9, the width of the n-type region 22 according to the present embodiment may be formed wider for the width of the p-type region 24 in comparison with the width of the n-type region 22 according to the first embodiment. Thus, as described later, the reverse recovery charge Qrr of the semiconductor device 1D can be further reduced.

The p-type impurity concentration of the p-type region 24 may be the same as or different from the p-type impurity concentration of the base region 23. The p-type impurity concentration of the p-type region 24 is, for example, 1×1017 cm-3 or more and 1×1022 cm-3 or less.

The p-type region 24 can be formed, for example, by implanting impurity ions of the second conductivity type in the side surface of the field plate trench FT after a process of forming the field plate trench FT described with reference to FIG. 5B.

As described above, in the third embodiment, by providing the projection portion 13a electrically connected to the source electrode 11 and the p-type region 24 in contact with the projection portion 13a, the depletion layer extends also from the p-type region 24 in the backward operation of the body diode. Therefore, the pressure-resistance of the Schottky barrier diode provided in the semiconductor device 1D can be significantly improved.

The sufficient pressure-resistance can be secured as described above, so that the width of the n-type region 22 (e.g., width W1 in FIG. 2) can be further widened. As a result, the ratio of the Schottky barrier diode to the body diode in the semiconductor device 1D can be further increased. Thus, the ratio of the electric currents that flow to the side of Schottky barrier diode when the electric currents flow to the drain electrode 12 from the source electrode 11, can be further increased and the reverse recovery charge Qrr of the semiconductor device 1D can be further reduced.

With reference to FIG. 9, the case where the upper end of the FP electrode 13 is located at a substantially same height as the height of the upper surface 2a of the semiconductor layer 2 similarly to the second embodiment was described, but the position of the upper end of the FP electrode 13 is optional. For example, as the first embodiment or the modification 2 of the second embodiment, the position of the upper end of the FP electrode 13 may be lower than the position of the lower end of the Schottky barrier metal 15, and as the modification 1 of the second embodiment, the position of the upper end of the FP electrode 13 may be higher than the position of the lower end of the Schottky barrier metal 15 and lower than the position of the upper surface 2a of the semiconductor layer 2.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a semiconductor layer having first and second surfaces and including a first semiconductor region of a first type;
a first electrode extending along the first surface;
a second electrode extending along the second surface;
a first insulation region extending from the first surface into the first semiconductor region;
a first conductive portion in the first insulation region and electrically connected to the first electrode;
a second insulation region extending from the first surface into the first semiconductor region and adjacent to the first insulation region;
a first control electrode in the second insulation region;
a second semiconductor region of the first type between and adjacent to the first and second insulation regions;
a second conductive portion adjacent to the second semiconductor region along the first surface, the second conductive portion being connected to the first electrode and forming a Schottky junction with the second semiconductor region;
a third semiconductor region of a second type on the first semiconductor region, the first control electrode being between the second and third semiconductor regions; and
a fourth semiconductor region of the first type between the third semiconductor region and the first electrode, wherein
the third and fourth semiconductor regions are electrically connected to the first electrode.

2. The semiconductor device according to claim 1, wherein an upper end of the first conductive portion is farther from the first surface than a lower end of the second semiconductor region in a direction from the first surface to the second surface.

3. The semiconductor device according to claim 1, wherein an upper end of the first conductive portion in a direction from the first surface to the second surface is on the first surface.

4. The semiconductor device according to claim 1, further comprising:
a projection portion projecting from the first conductive portion; and
a fifth semiconductor region of the second type that covers a surface of the projection portion, wherein
a width of the fifth semiconductor region is narrower than a width of the second semiconductor region.

5. The semiconductor device according to claim 1, wherein the second conductive portion is in the first insulation region and in contact with the second semiconductor region.

6. The semiconductor device according to claim 1, further comprising:
a second control electrode, wherein
the contact portion and the third semiconductor region are between the first and second control electrodes, and
a width of the second semiconductor region is narrower than a width of the third semiconductor region.

7. The semiconductor device according to claim 1, wherein a thickness of a part of the second insulation region facing the second semiconductor region is thicker than a thickness of another part of the second insulation region facing the third semiconductor region.

8. The semiconductor device according to claim 1, wherein the second conductive portion is platinum.

9. The semiconductor device according to claim 1, wherein the second conductive portion comprises at least one of platinum, cobalt, and nickel.

10. The semiconductor device according to claim 1, wherein an impurity concentration of the second semiconductor region is equal to or less than an impurity concentration of the first semiconductor region.

11. The semiconductor device according to claim 1, wherein the control electrode is polysilicon of the first type.

12. The semiconductor device according to claim 1, further comprising:
another first insulation region adjacent to the first insulation region and extending parallel to the first insulation region from the first surface into the first semiconductor region;
another first conductive portion in said another first insulation region and electrically connected to the first electrode;
another second insulation region extending from the first surface into the first semiconductor region and adjacent to said another first insulation region;
another first control electrode in said another second insulation region;
another second semiconductor region of the first type between and adjacent to said another first and second insulation regions;
another second conductive portion adjacent to said another second semiconductor region along the first surface, said another second conductive portion being connected to the first electrode and forming a Schottky junction with said another second semiconductor region;
another third semiconductor region of the second type on the first semiconductor region, said another first control electrode being between said another second and third semiconductor regions; and
another fourth semiconductor region of the first type between said another third semiconductor region and the first electrode, wherein
said another third and fourth semiconductor regions are electrically connected to the first electrode, and
when viewed in a cross section including an extension axis of each of the first insulation region and said another first insulation region, the second conductive portion, the first control electrode, said another second conductive portion, and said another first control electrode are arranged in this order.

13. A manufacturing method of a semiconductor device, comprising:
providing a semiconductor layer having first and second surfaces and including a first semiconductor region of a first type;
forming a first trench through the first surface;
forming a second trench through the first surface, the second trench being shallower than the first trench;
forming a first insulation region in the first trench;
forming a second insulation region in the second trench;
forming a first conductive portion in the first insulation region;
forming a control electrode in the second insulation region;
forming a second semiconductor region of the first type along the first surface and between the first and second insulation regions;
forming a third semiconductor region of a second type such that the control electrode and the second insulation region is between the second and third semiconductor regions;
forming a fourth semiconductor region of the first type between the third semiconductor region and the first surface;
removing a part of the first insulation region adjacent to the second semiconductor region along the first surface and forming a second conductive portion, which is a Schottky barrier metal;
removing a part of the third and fourth semiconductor regions and forming a contact portion;
cover the first surface except for the contact portion with an insulation film; and
forming a first electrode on the insulation film and the contact portion.

14. The manufacturing method according to claim 13, wherein an upper end of the first conductive portion is farther from the first surface than a lower end of the second semiconductor region in a direction from the first surface to the second surface.

15. The manufacturing method according to claim 13, wherein an upper end of the first conductive portion in a direction from the first surface to the second surface is on the first surface.

16. The manufacturing method according to claim 13, wherein the second conductive portion is in the first insulation region and in contact with the second semiconductor region.

17. The manufacturing method according to claim 13, wherein a thickness of a part of the second insulation region facing the second semiconductor region is thicker than a thickness of another part of the second insulation region facing the third semiconductor region.

18. The manufacturing method according to claim 13, wherein the second conductive portion is platinum.

19. The manufacturing method according to claim 13, wherein the second conductive portion comprises at least one of platinum, cobalt, and nickel.

20. The manufacturing method according to claim 13, wherein an impurity concentration of the second semiconductor region is equal to or less than an impurity concentration of the first semiconductor region.
